(19) United States
(12) Patent Application Publication
(10) Pub. No.: US 2023/0418151 A1
(43) Pub. Date: Dec. 28, 2023

(54) METHOD OF MANUFACTURING PHOTO MASKS AND SEMICONDUCTOR DEVICES

(71) Applicant: TAIWAN SEMICONDUCTOR MANUFACTURING COMPANY,LTD., Hsinchu (TW)

(72) Inventors: Wen-Hao CHENG, Hsinchu (TW); Chun Wei HSU, Taichung City (TW)

(21) Appl. No.: 18/103,289

(22) Filed: Jan. 30, 2023

Related U.S. Application Data
(60) Provisional application No. 63/356,416, filed on Jun. 28, 2022.

(51) Int. Cl. G03F 1/36; G03F 1/44; G03F 7/20

(52) U.S. Cl. CPC G03F 1/36; G03F 1/44; G03F 7/70625; G03F 7/7065

(57) ABSTRACT

In a method of manufacturing a photo mask, an original pattern layout including a plurality of patterns, each of which is defined by an opaque area, is obtained, a lower bound of an image-log-slope (ILS) is determined, sizes of the plurality of patterns are adjusted such that an exposure dose for the plurality of patterns decreases, while ILS values of the plurality of patterns do not fall below the lower bound of the ILS, an optical proximity correction (OPC) operation is performed on the plurality of patterns of which sizes have been adjusted to obtain mask data, and a photo mask is manufactured by using the mask data.

### RELATED APPLICATIONS

This application claims priority to U.S. Provisional Application No. 63/356,416 filed Jun. 28, 2022, the entire content of which is incorporated herein by reference.

### BACKGROUND

At semiconductor technology nodes of 7 nm or smaller, line-and-space (L/S) patterning requires pitch resolution in optical lithography smaller than about 32 nm. In general, even if extreme ultraviolet (EUV) lithography is employed, the resolution limitation by EUV single-exposure technology (SPT) is about 28 nm to about 34 nm.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows various parameters of a lithography operation.

FIG. 2A shows a relationship between an image log slope and a dose amount with respect to a pattern width.

FIG. 2B shows a structure of an EUV photo mask.

FIG. 2C shows a relationship between a target dimension and a mask dimension.

FIG. 3 is a flow chart of a sequential manufacturing operation of a semiconductor device according to an embodiment of the present disclosure.

FIG. 4 shows a flow chart of a sequential pattern correction operation according to an embodiment of the present disclosure.

FIG. 5A shows a flowchart of a method of making a semiconductor device, and FIGS. 5B, 5C, 5D and 5E show a sequential manufacturing operation of the method of making a semiconductor device in accordance with embodiments of present disclosure.

FIGS. 6A, 6B, 6C, 6D, 6E, 6F, 6G, 6H, 6I and 6J show various pattens subjected to the mask bias correction according to an embodiment of the present disclosure.

FIGS. 7A and 7B illustrate an apparatus for performing the mask size adjustment method according to an embodiment of the present disclosure.

FIG. 8 show simulation results of the effects of the mask size adjustment according to an embodiment of the present disclosure.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity. In the accompanying drawings, some layers/features may be omitted for simplification.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.” Further, in the following fabrication process, there may be one or more additional operations inbetween the described operations, and the order of operations may be changed. In the present disclosure, the phrase “at least one of A, B and C” means either one of A, B, C, A+B, A+C, B+C or A+B+C, and does not mean one from A, one from B and one from C, unless otherwise explained.

Disclosed embodiments relate to a semiconductor device, in particular, a complementary metal-oxide-semiconductor field effect transistor (CMOS FET), for example, a fin field effect transistor (FinFET) and its manufacturing method. The embodiments such as those disclosed herein are generally applicable not only to FinFETs but also to a planar FET, a double-gate FET, a surround-gate FET, an omega-gate FET or gate-all-around (GAA) FET, and/or a nanowire FET, or any suitable device having a three-dimensional channel structure. In the present disclosure, an improved mask pattern adjustment method to reduce a dose amount in a lithography operation, which in turn increases a through put of the lithography operation, will be explained.

EUV lithography can form nano-meter order patterns smaller than, e.g., about 20-40 nm, but requires a very expensive EUV lithography apparatus. Accordingly, improving productivity (throughput e.g., the number of semiconductor wafers processed per hour) of an EUV lithography operation is one of the key issues to reduce a manufacturing cost of a semiconductor device.

There are several ways to improve productivity of an EUV lithography operation. For example, decreasing a required dose amount per exposure of an EUV exposure light can improve the throughput of the EUV lithography operation. The required dose amount per exposure of an EUV exposure can be reduced by, for example, increasing a sensitivity of an EUV photo resist. The sensitivity of an EUV photo resist can generally be increased by optimizing the composition of the EUV photo resist by itself in some embodiments. The sensitivity of an EUV photo resist can also be increased (or the required dose amount can be reduced) by optimizing a post exposure baking (PEB) temperature (e.g., increasing the PEB temperature) performed after the exposure to the EUV light and before development of the exposed EUV photo resist in some embodiments, and by reducing a thickness of the EUV photo resist in other embodiments.

In other embodiments, the required dose amount can be reduced by adjusting a mask bias amount of an EUV photo mask. For example, decreasing an opaque (dark) area formed by an absorber pattern of an EUV reflective mask (increasing reflective or bright areas where no absorber pattern is disposed) can reduce a dose amount compared with an original mask pattern, when a positive tone resist process is used. The bright area is defined or surrounded by the dark (opaque) area. When a negative tone resist process is used, increasing an opaque (dark) area (decreasing reflective or bright areas) can reduce a dose amount compared with an original mask pattern. In the following embodiments, a positive tone resist process is assumed.

While reducing the dose amount to improve a throughput is preferable, at the same time, the EUV lithography operation requires a desired pattern resolution (minimum pattern dimension patternable by an EUV lithography operation) and/or pattern quality (e.g., smaller line edge roughness). Parameters in a lithography operation include a resolution, which may be defined by a half of a pattern pitch (of line and space patterns)=

$${k}_{1} \frac{λ}{( 1 + σ ) n sin θ} ;$$

a paraxial depth of focus (DOF), which may be defined as

$$\pm {k}_{2} \frac{λ}{n sin {e}^{2} θ} ;$$

a modulation, which may be defined as

$$\frac{{I}_{max} - {I}_{min}}{{I}_{max} + {I}_{min}} ;$$

an image log slope (ILS), which may be defined as

$$\frac{\partial ln I ( x )}{\partial x} ;$$

a normalized image log slope (NILS), which is defined as

$$\frac{\partial ln I}{\partial ln CD} ;$$

a mask error enhancement factor (MEEF), which may be defined as

$$\frac{\partial {CD}_{wafer}}{\partial {CD}_{mask}} ;$$

and an exposure latitude (EL), which may be defined as

$$\frac{Δ dose \%}{10 \% Δ CD} .$$

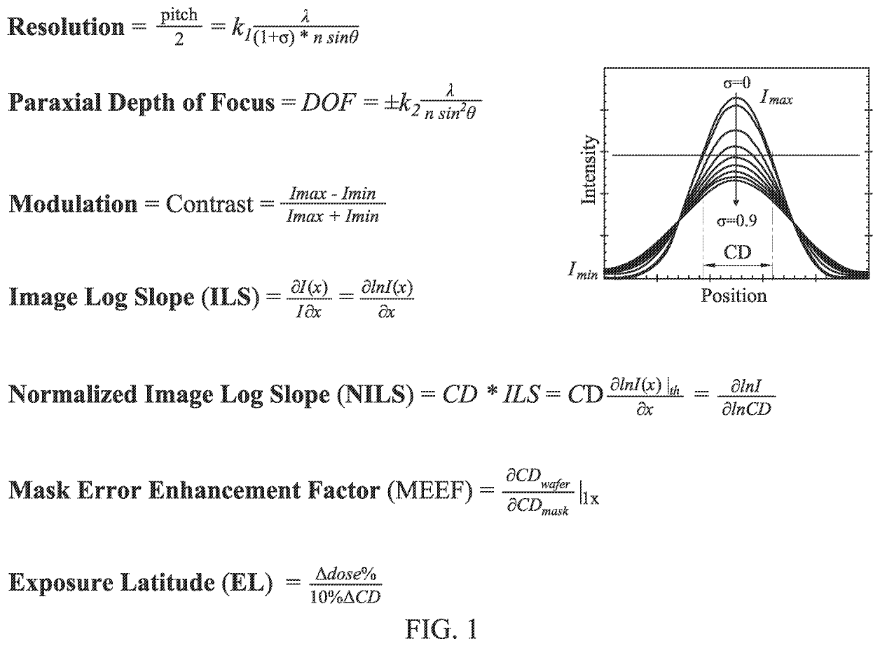

See, FIG. 1. In particular, the quality of an aerial image, such as an image log slope, determines the quality of resist patterns formed by EUV or DUV lithography.

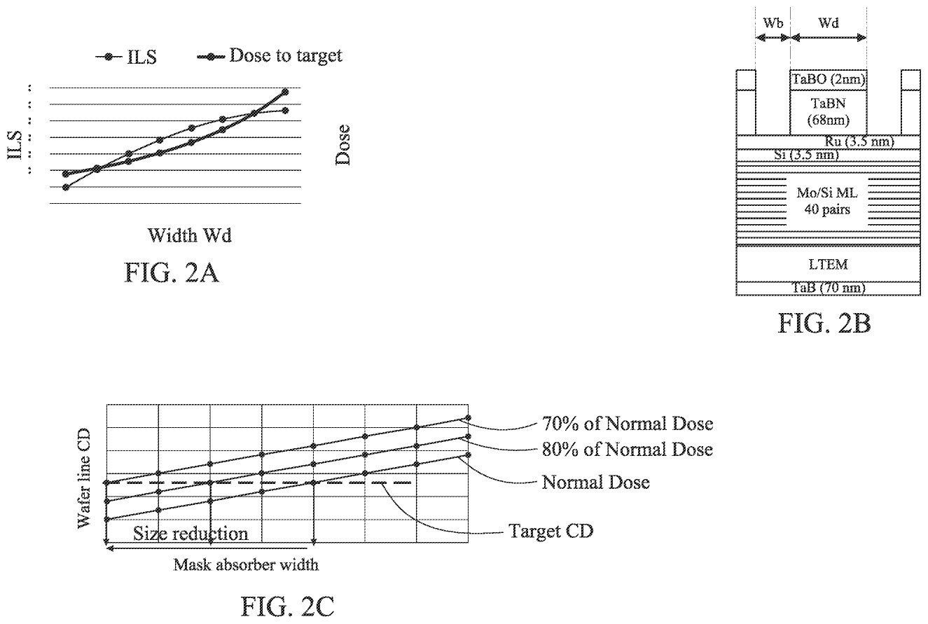

FIG. 2A shows a relationship between an image log slope (ILS) and a pattern width. FIG. 2B shows a cross sectional view of an EUV photo mask. In some embodiment, the EUV photo mask includes a substrate made of, for example a low thermal expansion material (LTEM), a multilayer reflective layer formed of alternately stacked Mo and Si layers, an intermediate layer formed of, for example Si, a capping layer formed of, for example Ru, an absorber layer formed of, for example TaBN, and an antireflective (or cover) layer formed of, for example, TaBO, as shown in FIG. 2B. In some embodiments, a backside conductive layer formed of, for example TaB is disposed. The absorber layer and the cover layer are patterned to expose parts of the capping layer, which correspond to bright regions that reflect the incident EUV light. The remaining parts of the absorber layer and the cover layer correspond to opaque or dark regions, which do not reflect the EUV light.

The pattern width Wd in FIGS. 2A and 2B is for an opaque line pattern surrounded by a light reflective area having a width Wb. As shown in FIG. 2A, a dose amount to obtain a desired pattern width decreases as a mask pattern width Wd decreases. FIG. 2C explains more about mask size adjustment and required dose reduction. When an original (not size adjusted) mask pattern is used, a normal dose is required to obtain the target dimension (CD: critical dimension) as a photo resist pattern on wafer. However, by reducing the mask size (absorber size), the required dose can be reduced by about 20% or about 30% to obtain the target CD on wafer as shown in FIG. 2C. When the dose amount is reduced, a through put of the lithography operation increases.

As set forth above, when the dose amount decreases, a through put of the lithography operation can increase. On the other hand, when the dose amount to obtain a desired pattern width decreases, the image log slope (ILS) also decreases, which means the aerial image quality decreases, which in turn decrease the quality of the resist pattern. For example, when the ILS decreases, the line edge (or line width) roughness may increase. That is, the dose amount (through put) and the ILS are in a trade-off relation. In the present disclosure, a low dose EUV lithography is achieved by adjusting mask bias amount while considering an aerial image quality of the patterns.

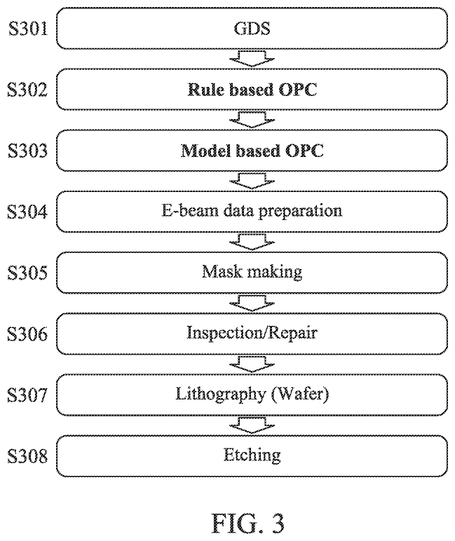

FIG. 3 shows a flow chart of a sequential manufacturing operation of a photo mask and a semiconductor device according to an embodiment of the present disclosure. It is understood that additional operations can be provided before, during, and after the operations of FIG. 3, and some of the operations described below can be replaced or eliminated, for additional embodiments of the method. The order of the operations/processes may be interchangeable.

At S301 of FIG. 3, an original pattern layout for a given layer is obtained. In some embodiments, the given layer is a gate electrode layer or a wiring layer. In some embodiments, the pattern layout is prepared in a Graphic Data System (GDS) format (e.g., GDS-II).

At S302 of FIG. 3, a pattern size of the patterns in the pattern layout is adjusted. In some embodiments, a lower bound of an image log slope is determined, and the size of the bright patterns is increased and/or the size of the dark patterns is decreased, such that the image log slope of the patterns does not fall below the lower bound (limit). In some embodiments, a size of a given bright pattern is increased and/or a size of a given dark pattern is decreased until the image log slope of the given pattern reaches the lower bound. In some embodiments, the lower bound of the image log slope is in a range from about 80 μm⁻¹ to about 110 μm⁻¹ and is in a range from about 90 μm⁻¹ to about 100 μm⁻¹ in other embodiments, depending on the parameters of the EUV lithography apparatus (e.g., numerical aperture (NA) of the optics of the EUV lithography apparatus) and/or resist process. In some embodiments, the lower bound of the image log slope is determined such that a developed photo resist pattern (or etched pattern) has an acceptable shape and/or dimensions, which may be predetermined in some embodiments.

In some embodiments, different NA values result in different image log slope ranges for the patterns. For example, when NA is 0.33, the range of the image log slope (of the calculated aerial image) is about 80-200 μm⁻¹, while the range of the image log slope is about 200-400 μm⁻¹, when NA is 0.55, for various patterns. This means that if the same lower bound of the image log slope (e.g., 80 μm⁻¹) is set, a larger mask bias amount (increase in bright regions) can be set for the higher NA condition.

In some embodiments, the sizing operation at S302 of FIG. 3 is performed by a rule based optical proximity correction (OPC) operation (e.g., a rule based logic operation).

At S303 of FIG. 3, the patterns of which sizes have been modified at S302 are further subjected to a model based OPC operation to further adjust the sizes of the patterns, to modify the shape of the patterns, and/or to add an extra (assisting) feature to the patterns. In some embodiments, an anchor pattern is determined. In some embodiments, the anchor pattern is a standard pattern to define the target dose in a lithography operation, and generally has a minimum pitch and/or dimension as defined by the design rule and/or a specific geometry (shape) defined by specific mask layer. In some embodiments, an anchor pattern sizing value is obtained by evaluating the trade-off of the image log slope value and a dose amount. In some embodiments, the anchor pattern sizing value is obtained for patterns with different dimensions. Then, one or more parameters of a model based OPC are adjusted by using the anchor pattern sizing value. By using the adjusted parameter, mask patterns are modified through model based OPC operation. In some embodiments, the model based OPC operation is performed such that the image log slope of the patterns does not fall below the lower bound (limit).

In some embodiments, the operations of S302 and S303 are combined as one operation.

In some embodiments, if a proper correction cannot be made in the model based OPC operation without violating the lower bound of the image log slope, the operation goes back to S302 and the lower bound of the image log slope is renewed (e.g., increased) and then mask size adjustment is performed with the renewed lower bound of the image log slope.

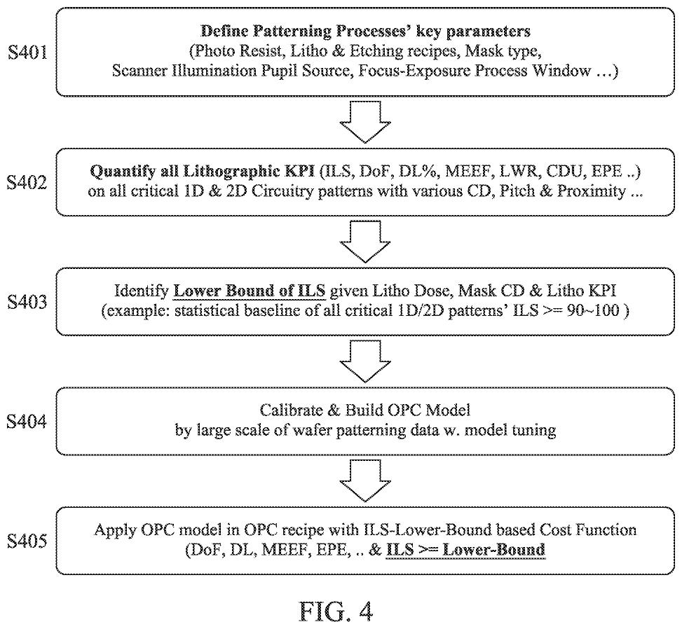

FIG. 4 shows a flow chart of a model based OPC operation in S303 of FIG. 3 according to an embodiment of the present disclosure. It is understood that additional operations can be provided before, during, and after the operations of FIG. 4, and some of the operations described below can be replaced or eliminated, for additional embodiments of the method. The order of the operations/processes may be interchangeable.

At S401 of FIG. 4, some key parameters for an EUV lithography process are determined. In some embodiments, the key parameters includes a photo resist property, an etching property, a mask type, an optical property of an EUV lithography apparatus and so on. In some embodiments, the photo resist property includes a resist thickness, a sensitivity of the resist, a developing property of the resist to a resist developer, a baking time and/or temperature, a reflection from the underlying layer, etc. In some embodiments, the etching property includes a gas, a plasma power, an etching selectivity, a process temperature, a process pressure, etc. In some embodiments, the photo mask subjected to the modification includes a binary mask or a phase shift mask, and a property of the photo mask includes a reflectivity of the photo mask, an absorption value of the absorber, a pellicle property, etc. In some embodiments, the optical property of an EUV lithography apparatus includes a wavelength of the EUV light, a coherency of the EUV light, a polarization of the EUV light, a numerical aperture (NA) of the optics, etc. Additionally, process parameters include a depth of focus (focus latitude), an exposure dose latitude, etc.

At S402, all key performance indicators (KPIs) are calculated based on one or more of the defined key parameters as defined in S401 for all of the critical patterns. In some embodiments, the key performance indicators includes an image log slope, a depth of focus, a dose latitude, a mask error enhancement factor (MEEF), a line width (edge) roughness (LWR or LER), a CD uniformity (CDU), an edge placement error (EPE), etc. In some embodiments, the patterns include one dimensional patterns extending in one direction and two dimensional patterns extending in two or more directions. In some embodiments, the critical patterns include patterns having dimensions equal to or smaller than a threshold dimension, and/or patterns with a separation (space) to adjacent pattern(s) equal to or smaller than a threshold separation. In some embodiments, a specific pattern may be excluded even if the pattern satisfies the critical pattern definition.

In S403 of FIG. 4, a lower bound of the image log slope is determined. In some embodiments, image log slope values are calculated for all critical patterns and the minimum value of the image log slopes is determined as the lower bound of the image log slope. In other embodiments, the standard deviation (σ) of the image log slope values are calculated, and the value that the average of the image log slope values minus n×σ is set as the lower bound of the image log slope. In some embodiments, n is 2, 3, 4, 5 or 6. In some embodiments, the lower bound of the image log slope is in a range from about 80 μm⁻¹ to about 110 μm⁻¹ and is in a range from about 90 μm⁻¹ to about 100 μm⁻¹ in other embodiments.

In S404 of FIG. 4, one or more parameters of the model based OPC are determined or adjusted based on one or more of the process parameters and/or the key performance indicators.

In S405 of FIG. 4, the model based OPC is performed on the mask patterns considering the lower bound of the image log slope. In some embodiments, the model based OPC is performed such that none of the corrected pattens has the image log slope of the patterns smaller than the lower bound (limit) of the image log slope. In some embodiments, the model based OPC is performed on only the critical patterns. In some embodiments, the model based OPC with considering the lower bound of the image log slope is performed only on the critical patterns. In some embodiments, the after the model based OPC operation, the image log slope of most of the patterns (e.g., 80% or more) decrease, but does not fall below the lower bound. In some embodiments, the image log slope of some of the patterns (e.g., 1-10%) remain unchanged. In some embodiments, the image log slope of most of the patterns (e.g., 1-10%) increases.

In some embodiments, the average of the image log slope values after the model based OPC operation is smaller than the average of the image log slope values of the original mask patterns. In some embodiments, the average of the image log slope values after the model based OPC operation is about 30% to about 80% of the average of the image log slope values of the original mask patterns. In some embodiments, the standard deviation (a) of the image log slope values after the model based OPC operation is smaller than the standard deviation of the image log slope values of the original mask patterns. In some embodiments, the standard deviation (a) of the image log slope values after the model based OPC operation is about 30% to about 80% of the standard deviation of the image log slope values of the original mask patterns.

At S304, mask data for electron beam writing is prepared. Then, at S305, an EUV photo mask is manufactured from a mask blank for an EUV photo mask.

In some embodiments, the mask blank includes a hard mask layer disposed over the cover layer. In the fabrication of an EUV photo mask, a first photoresist layer is formed over the hard mask layer of the EUV photo mask blank, and the photoresist layer 35 is selectively exposed to actinic radiation (e.g., electron beam) using the mask data. The selectively exposed first photoresist layer is developed to form a resist pattern. Next, the resist pattern is extended into the hard mask layer exposing portions of the cover layer. The hard mask layer is patterned by etching in some embodiments, using a suitable wet or dry etchant that is selective to the cover layer. Then, the hard mask pattern is extended into the cover layer and the absorber layer exposing portions of the capping layer, and then the hard mask layer is removed. In some embodiments, a second photoresist layer is formed over the cover layer, and the second photoresist layer is selectively exposed to actinic radiation, such as electron beam. The selectively exposed second photoresist layer is developed to form a pattern for a black border surrounding the circuit patterns. A black border is a frame shaped area created by removing all the multilayers on the EUV photo mask in the region around a circuit pattern area. The pattern in the second photoresist layer is extended into the cover layer, the absorber layer, the capping layer, and Mo/Si multilayer forming the black border pattern.

At S306 of FIG. 3, the fabricated EUV photo mask is subjected to an inspection operation and if necessary, a repair operation is performed to remove defects or correct defective patterns. At A307 and S308 of FIG. 3, the EUV photo mask is used in an EUV lithography operation to form a circuit pattern over a semiconductor substrate, and an etching operation is performed.

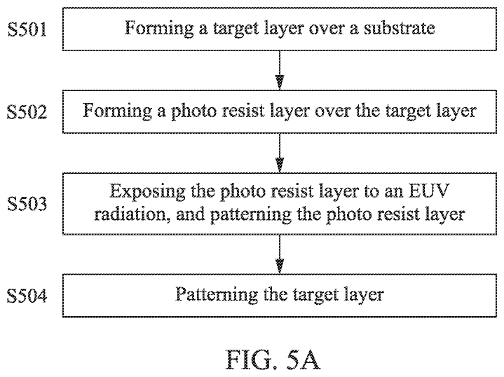

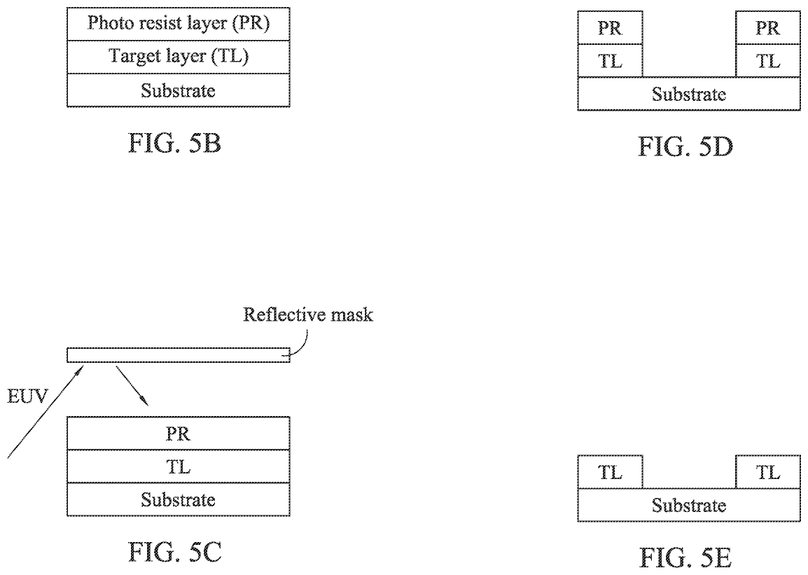

FIG. 5A shows a flowchart of a method of making a semiconductor device, and FIGS. 5B, 5C, 5D and 5E show a sequential manufacturing operation of the method of making a semiconductor device in the operations of S307 and S308 in accordance with embodiments of present disclosure. A semiconductor substrate or other suitable substrate to be patterned to form an integrated circuit thereon is provided. In some embodiments, the semiconductor substrate includes silicon. Alternatively or additionally, the semiconductor substrate includes germanium, silicon germanium or other suitable semiconductor material, such as a Group III-V semiconductor material. At S501 of FIG. 5A, a target layer to be patterned is formed over the semiconductor substrate. In certain embodiments, the target layer is the semiconductor substrate. In some embodiments, the target layer includes a conductive layer, such as a metallic layer or a polysilicon layer; a dielectric layer, such as silicon oxide, silicon nitride, SiON, SiOC, SiOCN, SiCN, hafnium oxide, or aluminum oxide; or a semiconductor layer, such as an epitaxially formed semiconductor layer. In some embodiments, the target layer is formed over an underlying structure, such as isolation structures, transistors or wirings. At S502, of FIG. 5A, a photo resist layer is formed over the target layer, as shown in FIG. 5B. The photo resist layer is sensitive to the radiation from the exposing source during a subsequent photolithography exposing process. In the present embodiment, the photo resist layer is sensitive to EUV light used in the photolithography exposing process. The photo resist layer may be formed over the target layer by spin-on coating or other suitable technique. The coated photo resist layer may be further baked to drive out solvent in the photo resist layer. At S503 of FIG. 5A, the photoresist layer is patterned using an EUV reflective mask as set forth above, as shown in FIG. 5B. The patterning of the photoresist layer includes performing a photolithography exposing process by an EUV exposing system using the EUV mask. During the exposing process, the integrated circuit (IC) design pattern defined on the EUV mask is imaged to the photoresist layer to form a latent pattern thereon. The patterning of the photoresist layer further includes developing the exposed photoresist layer to form a patterned photoresist layer having one or more openings. In one embodiment where the photoresist layer is a positive tone photoresist layer, the exposed portions of the photoresist layer are removed during the developing process. The patterning of the photoresist layer may further include other process steps, such as various baking steps at different stages. For example, a post-exposure-baking (PEB) process may be implemented after the photolithography exposing process and before the developing process.

At S504 of FIG. 5A, the target layer is patterned utilizing the patterned photoresist layer as an etching mask, as shown in FIG. 5D. In some embodiments, the patterning the target layer includes applying an etching process to the target layer using the patterned photoresist layer as an etch mask. The portions of the target layer exposed within the openings of the patterned photoresist layer are etched while the remaining portions are protected from etching. Further, the patterned photoresist layer may be removed by wet stripping or plasma ashing, as shown in FIG.

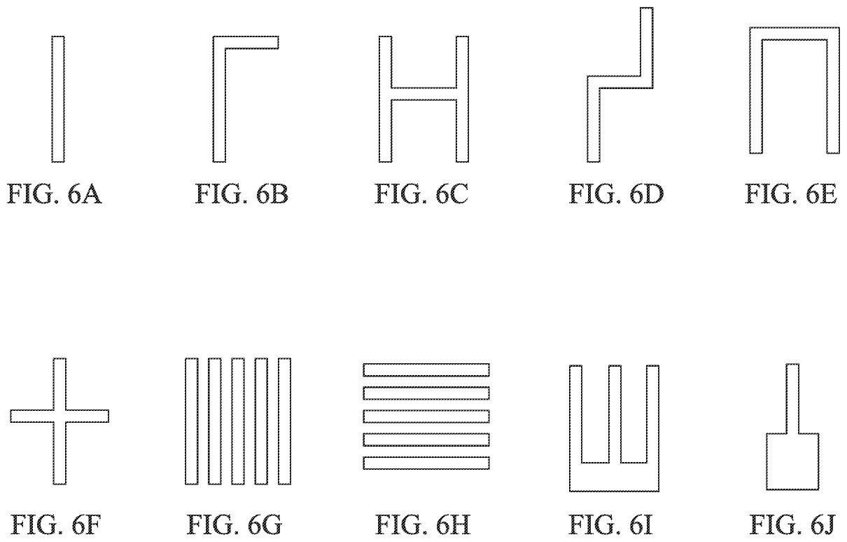

In some embodiments, the lower bound of the image log slope is calculated or determined for groups of patterns. In some embodiments, one or more of the groups include a simple line pattern extending in one direction (e.g., X direction) as shown in FIG. 6A. In some embodiments, this group includes a line pattern extending in Y direction. In some embodiments, the simple line pattern is isolated from other patterns by a space, for example, 5 times or more of the width of the line pattern. In some embodiments, one or more of the groups include two dimensional patterns as shown in FIGS. 6A-6F. In some embodiments, the two dimensional patterns include an L-shape pattern as shown in FIG. 6B, an H-shape pattern as shown in FIG. 6C, a crank shape pattern as shown in FIG. 6D, a H-shape pattern as shown in FIG. 6E, and/or a cross shape pattern as shown in FIG. 6F. In some embodiments, one or more of the groups include periodic patterns (the space to adjacent pattern is 4 times or less of (or same as) the width of the patterns, as shown in FIGS. 6G and 6H. In some embodiments, the patterns in FIGS. 6A-6H have the same width, respectively. In some embodiments, as shown in FIGS. 61 and 6J, one or more groups includes patterns with different widths.

In some embodiments, the patterns subjected to the OPC are grouped based on the dimension and/or shape of the patterns, and the lower bound of the image log slope is determined for each of the groups of patterns. For example, an image log slope of some patterns may be highly sensitive to the pattern width (steeper slope in FIG. 2A), while an image log slope of other patterns may not be so sensitive to the pattern width. In such a case, a relatively higher value is set for the lower bound of the image log slope for the patterns that are sensitive to the pattern width than the patterns that are less sensitive. In some embodiments, at least one of the groups has a different lower bound of the image log slope.

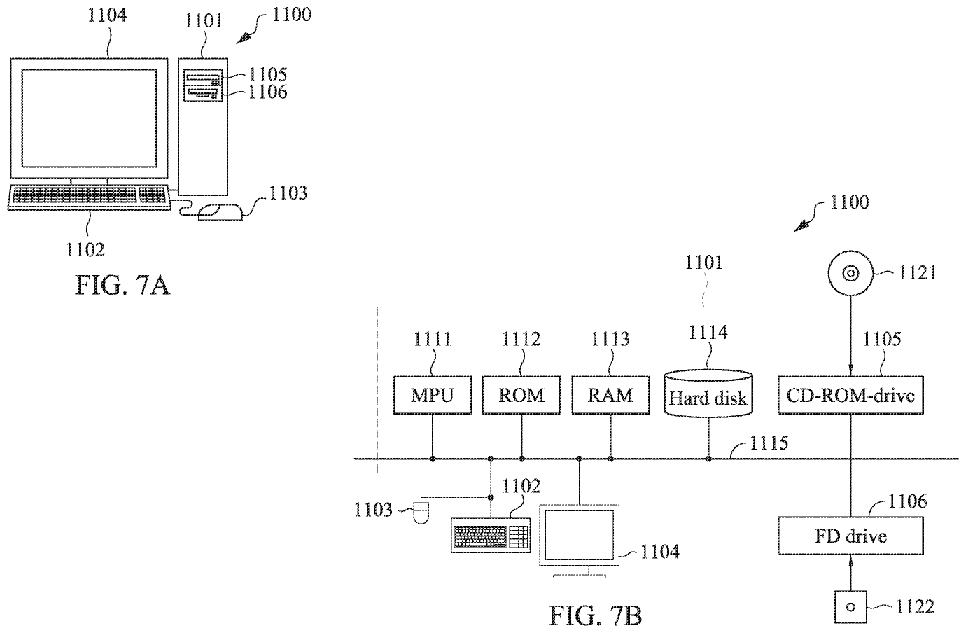

FIGS. 7A and 7B illustrate an apparatus for performing the mask size adjustment (rule based OPC) and the model based OPC for an EUV photo mask for a semiconductor circuit in accordance with some embodiments of the disclosure. In some embodiments, the apparatus is an optical simulator and/or a mask data preparation apparatus.

FIG. 7A is a schematic view of a computer system (mask layout system) that executes the process for preparing the lithographic mask data according to one or more embodiments as described above. All of or a part of the processes, method and/or operations of the foregoing embodiments can be realized using computer hardware and computer programs executed thereon. The operations include pattern size adjustments as explained above. In FIG. 7A, a computer system 1100 is provided with a computer 1101 including an optical disk read only memory (e.g., CD-ROM or DVD-ROM) drive 1105 and a magnetic disk drive 1106, a keyboard 1102, a mouse 1103, and a monitor 1104.

FIG. 7B is a diagram showing an internal configuration of the computer system 1100. The computer 1101 is provided with, in addition to the optical disk drive 1105 and the magnetic disk drive 1106, one or more processors 1111, such as a micro processing unit (MPU), a read only memory (ROM) 1112 in which a program, such as a boot up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

The program for causing the computer system 1100 to execute the process for adjusting the mask pattern dimensions in the foregoing embodiments may be stored in an optical disk 1121 or a magnetic disk 1122, which are inserted into the optical disk drive 1105 or the magnetic disk drive 1106, and transmitted to the hard disk 1114. Alternatively, the program may be transmitted via a network (not shown) to the computer 1101 and stored in the hard disk 1114. At the time of execution, the program is loaded into the RAM 1113. The program may be loaded from the optical disk 1121 or the magnetic disk 1122, or directly from a network. The program does not necessarily have to include, for example, an operating system (OS) or a third party program to cause the computer 1101 to execute the process for manufacturing the lithographic mask of a semiconductor device in the foregoing embodiments. The program may only include a command portion to call an appropriate function (module) in a controlled mode and obtain desired results.

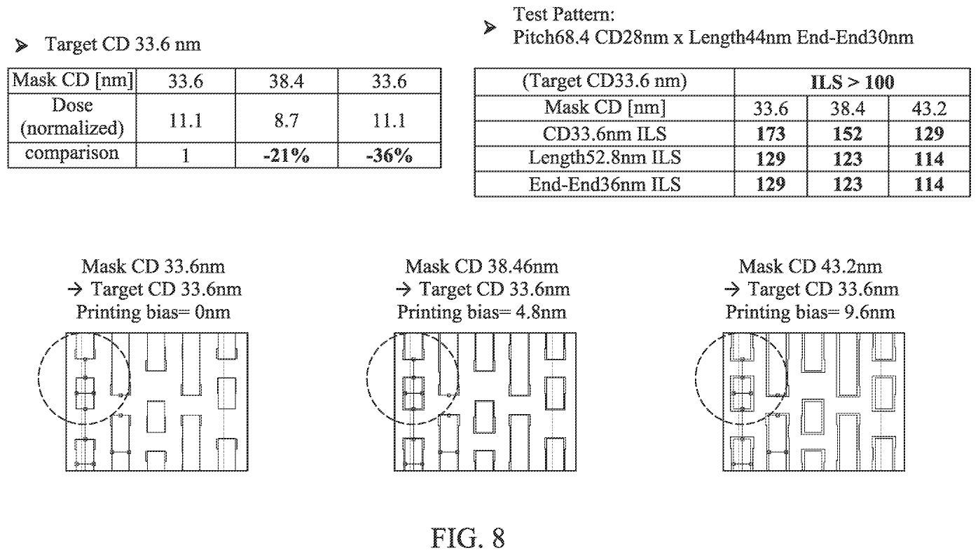

FIG. 8 show simulation results of the effects of the mask size adjustment. In the simulation, a rectangular bright pattern having an original with of 33.6 nm (target width) is evaluated. As shown in FIG. 8, the required dose (normalized dose) for printing a resist pattern having the target width (33.6 nm) decreases up to 36% by increasing the mask pattern width. On the other hand, the image log slope decreases with the increase of the mask pattern width. As shown in FIG. 8, the image log slope of the original pattern is 173 μm⁻¹ for a given lithography process condition, and the image log slope decreases to 129 μm⁻¹ for the broader mask width of 43.2 nm (4.8 nm bias on one side). Since the lower bound of the image log slope is set at 100 is 100 μm⁻¹, this mask bias is acceptable. Similarly, the image log slope values of other dimensions, such as a pattern length or an end-to-end space are also evaluated, and are confirmed to satisfy the lower bound of the image log slope more than 100 μm⁻¹.

The foregoing technologies are applicable to fabrication of any semiconductor devices such as a logic circuit (e.g., CPU, a graphic processor, etc.), a memory (e.g., a static random access memory, a dynamic random access memory, an electrically erasable programmable read-only memory, a flash memory, a read only memory, etc.) or other semiconductor device. Further, the foregoing technologies are applicable to a DUV lithography using a transmissive photo mask. The dimensions of the light transmissive regions are adjusted (increased) with considering the lower bound of the image log slope calculated for a DUC lithography process condition.

In the foregoing embodiments, the dimensions of the bright (light reflective or transmissive regions) are adjusted (increased) with considering the lower bound of the image log slope, which results in reductio of the dose in a lithography process. The decrease in the dose results in increasing through put, which results in reductio of manufacturing cost of semiconductor devices.

It will be understood that not all advantages have been necessarily discussed herein, no particular advantage is required for all embodiments or examples, and other embodiments or examples may offer different advantages.

In accordance with an aspect of the present disclosure, in a method of manufacturing a photo mask, an original pattern layout including a plurality of patterns, each of which is defined by an opaque area, is obtained, a lower bound of an image-log-slope (ILS) is determined, sizes of the plurality of patterns are adjusted such that an exposure dose for the plurality of patterns decreases, while ILS values of the plurality of pattern do not fall below the lower bound of the ILS, an optical proximity correction (OPC) operation is performed on the plurality of patterns of which sizes have been adjusted to obtain mask data, and a photo mask is manufactured by using the mask data. In one or more of the foregoing and following embodiments, the lower bound of the ILS is determined based at least one of an exposure dose, a pattern size, a line-width roughness (LWR) of a developed resist pattern, a focus margin, a mask error enhancement factor, an edge placement error or a CD uniformity. In one or more of the foregoing and following embodiments, the lower bound of the ILS is set from 90 μm⁻¹ to 100 μm⁻¹. In one or more of the foregoing and following embodiments, the sizes the plurality of patterns are increased. In one or more of the foregoing and following embodiments, an ILS value of at least one of the plurality of patterns decreases. In one or more of the foregoing and following embodiments, the ILS values of the plurality of patterns decrease. In one or more of the foregoing and following embodiments, initial ILS values for the plurality of patterns are obtained before the size adjustment, and the lower bound of the ILS is determined based in the initial ILS values. In one or more of the foregoing and following embodiments, the lower bound of the ILS is equal to a minimum of the initial ILS values.

In accordance with another aspect of the present disclosure, in a method of manufacturing a photo mask, an original pattern layout including a plurality of patterns, each of which is defined by an opaque area is obtained, a lower bound of an image-log-slope (ILS) is determined, an optical proximity correction (OPC) operation is performed on the plurality of patterns such that an exposure dose for the plurality of patterns decreases, while ILS values of the plurality of pattern do not fall below the lower bound of the ILS, and a photo mask is manufactured by using the mask data. In one or more of the foregoing and following embodiments, a toral areas of the plurality of patterns increases after the OPC operation. In one or more of the foregoing and following embodiments, an average ILS values of the plurality of patterns decreases after the OPC operation. In one or more of the foregoing and following embodiments, the lower bound of the ILS is determined based at least one of an exposure dose, a pattern size, a line-width roughness (LWR) of a developed resist pattern, a focus margin, a mask error enhancement factor, an edge placement error or a CD uniformity. In one or more of the foregoing and following embodiments, the lower bound of the ILS is set from 80 μm⁻¹ to 100 μm⁻¹. In one or more of the foregoing and following embodiments, initial ILS values for the plurality of patterns are obtained before the OPC operation, and the lower bound of the ILS is determined based in the initial ILS values. In one or more of the foregoing and following embodiments, the lower bound of the ILS is greater than a minimum of the initial ILS values.

In accordance with another aspect of the present disclosure, in a method of manufacturing a photo mask, an original pattern layout including a plurality of patterns, each of which is defined by an opaque area is acquired, the plurality of patterns are classified into a plurality of groups based on at least one of a size or a shape, a lower bound of an image-log-slope (ILS) for each of the plurality of groups is determined, an optical proximity correction (OPC) operation is performed on the plurality of patterns such that an exposure dose for the plurality of patterns decreases, while ILS values for the plurality of groups do not fall below the lower bound of the ILS, and a photo mask is manufactured by using the mask data. In one or more of the foregoing and following embodiments, at least one group of the plurality of groups includes patterns extending in one direction, and at least one group of the plurality of groups includes patterns extending in two directions. In one or more of the foregoing and following embodiments, an average ILS values of the plurality of patterns decreases after the OPC operation. In one or more of the foregoing and following embodiments, the lower bound of the ILS is determined based at least one of an exposure dose, a pattern size, a line-width roughness (LWR) of a developed resist pattern, a focus margin, a mask error enhancement factor, an edge placement error or a CD uniformity. In one or more of the foregoing and following embodiments, initial ILS values for the plurality of groups are obtained before the OPC operation, and the lower bound of the ILS is determined based in the initial ILS values.

In accordance with another aspect of the present disclosure, an apparatus includes a processor, and a non-transitory memory storing a program. The program, when executed by the processor, causes the processor to perform the method according to one or more of the foregoing embodiments (methods).

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a photo mask, comprising:
acquiring an original pattern layout including a plurality of patterns, each of which is defined by an opaque area;
determining a lower bound of an image log slope (ILS);
adjusting sizes of the plurality of patterns such that an exposure dose for the plurality of patterns decreases, while ILS values of the plurality of pattern do not fall below the lower bound of the ILS;
performing an optical proximity correction (OPC) operation on the plurality of patterns of which sizes have been adjusted to obtain mask data; and
manufacturing a photo mask by using the mask data.

2. The method of claim 1, wherein the lower bound of the ILS is determined based on at least one of an exposure dose, a pattern size, a line-width roughness (LWR) of a developed resist pattern, a focus margin, a mask error enhancement factor, an edge placement error or a critical dimension (CD) uniformity.

3. The method of claim 1, wherein the lower bound of the ILS is set from 90 μm⁻¹ to 100 μm⁻¹.

4. The method of claim 1, wherein the sizes the plurality of patterns are increased during the adjusting sizes of the plurality of patterns.

5. The method of claim 4, wherein an ILS value of at least one of the plurality of patterns decreases.

6. The method of claim 4, wherein the ILS values of the plurality of patterns decrease.

7. The method of claim 1, further comprising obtaining initial ILS values for the plurality of patterns before the size adjustment,
wherein the lower bound of the ILS is determined based in the initial ILS values.

8. The method of claim 7, wherein the lower bound of the ILS is equal to a minimum of the initial ILS values.

9. A method of manufacturing a photo mask, comprising:
acquiring an original pattern layout including a plurality of patterns, each of which is defined by an opaque area;
determining a lower bound of an image log slope (ILS);
performing an optical proximity correction (OPC) operation on the plurality of patterns to obtain mask data such that an exposure dose for the plurality of patterns decreases, while ILS values of the plurality of pattern do not fall below the lower bound of the ILS; and
manufacturing a photo mask by using the mask data.

10. The method of claim 9, wherein a total area of the plurality of patterns increases after the OPC operation.

11. The method of claim 10, wherein an average ILS value of the plurality of patterns decreases after the OPC operation.

12. The method of claim 9, wherein the lower bound of the ILS is determined based on at least one of an exposure dose, a pattern size, a line-width roughness (LWR) of a developed resist pattern, a focus margin, a mask error enhancement factor, an edge placement error or a critical dimension (CD) uniformity.

13. The method of claim 9, wherein the lower bound of the ILS is set from 80 μm⁻¹ to 100 μm⁻¹.

14. The method of claim 9, further comprising obtaining initial ILS values for the plurality of patterns before the OPC operation,
wherein the lower bound of the ILS is determined based in the initial ILS values.

15. The method of claim 14, wherein the lower bound of the ILS is greater than a minimum of the initial ILS values.

16. A method of manufacturing a photo mask, comprising:
acquiring an original pattern layout including a plurality of patterns, each of which is defined by an opaque area;
classifying the plurality of patterns into a plurality of groups based on at least one of a size or a shape;
determining a lower bound of an image log slope (ILS) for each of the plurality of groups;
performing an optical proximity correction (OPC) operation on the plurality of patterns to obtain mask data such that an exposure dose for the plurality of patterns decreases, while ILS values for the plurality of groups do not fall below the lower bound of the ILS; and
manufacturing a photo mask by using the mask data.

17. The method of claim 16, wherein at least one group of the plurality of groups includes patterns extending in one direction, and at least one group of the plurality of groups includes patterns extending in two directions.

18. The method of claim 16, wherein an average ILS values of the plurality of patterns decreases after the OPC operation.

19. The method of claim 16, wherein the lower bound of the ILS is determined based on at least one of an exposure dose, a pattern size, a line-width roughness (LWR) of a developed resist pattern, a focus margin, a mask error enhancement factor, an edge placement error or a critical dimension (CD) uniformity.

20. The method of claim 16, further comprising obtaining initial ILS values for the plurality of groups before the OPC operation,
wherein the lower bound of the ILS is determined based in the initial ILS values.
